(19) United States
(12) Patent Application Publication
(10) Pub. No.: US 2023/0238775 A1
(43) Pub. Date: Jul. 27, 2023

(54) MANIPULATING BEAM DIVERGENCE OF MULTI-JUNCTION VERTICAL CAVITY SURFACE EMITTING LASER

(71) Applicant: Lumentum Operations LLC, San Jose, CA (US)

(72) Inventors: Jun YANG, Cupertino, CA (US); Matthew Glenn PETERS, Menlo Park, CA (US); Guowei ZHAO, Milpitas, CA (US); Benjamin KESLER, Sunnyvale, CA (US); Eric R. HEGBLOM, Sunnyvale, CA (US)

(21) Appl. No.: 17/654,716

(22) Filed: Mar. 14, 2022

Related U.S. Application Data
(60) Provisional application No. 63/267,216, filed on Jan. 27, 2022.

(51) Int. Cl. H01S 5/183; H01S 5/34

(52) U.S. Cl. CPC H01S 5/18397; H01S 5/18361; H01S 5/3416; H01S 5/18311; H01S 5/18305

(57) ABSTRACT

A multi junction vertical cavity surface emitting laser (VCSEL) may comprise a substrate, a top contact, and a stack comprising a set of layers formed between the substrate and the top contact. In some implementations, the set of layers formed between the substrate and the top contact may comprise a cavity comprising a first active region, a second active region, and a tunnel junction connecting the first active region and the second active region, a first distributed Bragg reflector (DBR) pair comprising a high-contrast p-type DBR (p-DBR) and a low-contrast p-DBR between the cavity and the top contact, and a second DBR pair comprising a high-contrast n-type DBR (n-DBR) and a low-contrast n-DBR between the cavity and the substrate. The low-contrast p-DBR and the low-contrast n-DBR are located on an inner side of the stack, and the high-contrast p-DBR and the high-contrast n-DBR are located on an outer side of the stack.

### CROSS-REFERENCE TO RELATED APPLICATION

This Patent application claims priority to U.S. Provisional Patent Application No. 63/267,216, filed on Jan. 27, 2022, and entitled “MANIPULATING BEAM DIVERGENCE OF MULTI-JUNCTION VERTICAL CAVITY SURFACE EMITTING LASER” The disclosure of the prior Application is considered part of and is incorporated by reference into this Patent Application.

### TECHNICAL FIELD

The present disclosure relates generally to a vertical cavity surface emitting laser (VCSEL) and to a multi-junction VCSEL including one or more low-contrast mirrors to manipulate a beam divergence of the multi junction VCSEL.

### BACKGROUND

A VCSEL is a semiconductor laser, more specifically a diode laser with a monolithic laser resonator, where light is emitted in a direction perpendicular to a chip surface. Typically, the laser resonator includes two distributed Bragg reflector (DBR) mirrors that are parallel to the chip surface, with an active region (including one or more quantum wells) disposed between the two DBR mirrors to generate light. Commonly, the upper and lower mirrors of a VCSEL are doped as p-type and n-type materials, respectively, thereby forming a diode junction.

### SUMMARY

In some implementations, a multi junction VCSEL includes a substrate; a top contact; and a set of layers, formed between the substrate and the top contact, comprising: a high-contrast p-type DBR (p-DBR); a high-contrast n-type distributed Bragg reflector (n-DBR); a cavity comprising a first active region, a second active region, and a tunnel junction connecting the first active region and the second active region, wherein the cavity is disposed between the high-contrast p-DBR and the high-contrast n-DBR; and a low-contrast n-DBR disposed between the high-contrast n-DBR and the cavity.

In some implementations, a device includes a substrate; a top contact; and a stack comprising a set of layers, formed between the substrate and the top contact, the set of layers comprising: a cavity comprising a first active region, a second active region, and a tunnel junction connecting the first active region and the second active region; a first DBR pair comprising a high-contrast p-DBR and a low-contrast p-DBR between the cavity and the top contact; and a second DBR pair comprising a high-contrast n-DBR and a low-contrast n-DBR between the cavity and the substrate, wherein the low-contrast p-DBR and the low-contrast n-DBR are located on an inner side of the stack, and wherein the high-contrast p-DBR and the high-contrast n-DBR are located on an outer side of the stack.

In some implementations, a multi junction VCSEL includes an n-type substrate; an n-type top contact; and a stack comprising a set of layers, formed between the n-type substrate and the n-type top contact, the set of layers comprising: a cavity comprising a first active region, a second active region, and a first tunnel junction connecting the first active region and the second active region; an upper n-DBR pair comprising an upper high-contrast n-DBR and an upper low-contrast n-DBR disposed between the cavity and the n-type top contact; a lower n-DBR pair comprising a lower high-contrast n-DBR and a lower low-contrast n-DBR disposed between the cavity and the n-type substrate; and a second tunnel junction disposed between the cavity and the upper n-DBR pair or the lower n-DBR pair, wherein the upper low-contrast n-DBR and the lower low-contrast n-DBR are located on an inner side of the stack, and wherein the upper high-contrast n-DBR and the lower high-contrast n-DBR are located on an outer side of the stack.

### BRIEF DESCRIPTION OF THE DRAWINGS

FIGS. 1A-1B are diagrams respectively depicting a top view of an example emitter and a cross-sectional view of the example emitter.

FIGS. 2A-2D are diagrams depicting cross-sectional views of example structures for a multi-junction emitter described herein.

FIGS. 3A-3C are diagrams depicting examples of refractive index profile differences between high-contrast outer mirrors and low-contrast inner mirrors in an example multi-junction emitter described herein.

### DETAILED DESCRIPTION

The following detailed description of example implementations refers to the accompanying drawings. The same reference numbers in different drawings may identify the same or similar elements.

A vertical-emitting device, such as a vertical cavity surface emitting laser (VCSEL), is a laser in which a laser beam is emitted in a direction vertical to a surface of a substrate (e.g., vertically from a surface of a semiconductor wafer). In contrast to edge-emitting devices, vertical-emitting devices may allow for testing to occur at intermediate steps of wafer fabrication. In some cases, multiple vertical-emitting devices may be arranged to form an array. For example, multiple vertical-emitting devices (herein referred to as emitters) may be arranged to form a VCSEL array, such as a grid VCSEL array (e.g., where multiple emitters are uniformly spaced and oxidation trenches may be shared by two or more emitters) or a non-grid VCSEL array (e.g., where multiple emitters are not uniformly spaced and each emitter requires a set of oxidation trenches which may or may not be shared).

In a typical single-junction VCSEL, an active region is embedded in a cavity of the VCSEL between a top mirror (e.g., a p-type distributed Bragg reflector (p-DBR)) and a bottom mirror (e.g., an n-type DBR (n-DBR)). For example, the active region may include a multiple quantum well (MQW) structure that forms a positive-intrinsic-negative (p-i-n) junction. In some examples, a multi junction VCSEL may include multiple (e.g., two, three, or more) active regions or p-i-n junctions that are connected vertically in series with low-resistance tunnel junctions between the active regions. A tunnel junction is a positive-negative (p-n) junction formed by very heavily doped p-type and n-type semiconductor materials (denoted p++ and n++, respectively), which may have a doping level from 10¹⁹ to 10²⁰ cm⁻³. Due to a quantum tunneling effect, electrons are converted to holes through the tunnel junction, whereby the multi-junction VCSEL can generate multiple photons by each injected electron. Relative to a single-junction VCSEL with one active region, a multi junction VCSEL with multiple active regions connected in series with one or more low-resistance tunnel junctions provides higher slope efficiency (e.g., in watts per amp) and higher power conversion efficiency. Accordingly, a multi-junction VCSEL or an array of multi-junction VCSELs provides a high-brightness laser source that is useful for light detection and ranging (LIDAR) applications and/or three-dimensional (3D) sensing applications (e.g., direct time-of-flight (dToF) applications and/or indirect time-of-flight (iToF) applications), among other examples.

However, relative to a single junction VCSEL, one challenge that may arise when designing a multi junction VCSEL is that using more active regions results in a much higher total gain compared to a single junction VCSEL, which can promote lasing with more high-order modes and higher angle transverse modes than single junction VCSELs. For example, in a single junction VCSEL, optical losses may suppress high-order and higher angle transverse modes that may cause beam divergence, which may be relatively higher in multi junction VCSELs because the higher total gain achieved by using multiple active regions may overcome the optical losses that otherwise suppress the high-order and higher angle transverse modes in single junction VCSELs. Furthermore, another challenge for multi junction VCSEL designs is controlling a current injection profile as electrons and holes enter into the outer active regions and travel through each active region and tunnel junction interface. Although current injection and mode profiles can be controlled in a single junction VCSEL using a single oxide aperture very close to a single active region, adding oxide apertures between each active region in a multi-junction VCSEL can have various drawbacks. For example, additional oxide apertures may increase optical loss and/or support even higher angle modes due to low-index confinement. Additionally, inserting more oxide apertures may be ineffective due to the tunnel junction(s) with highly doped layers around a voltage barrier, potentially causing lateral current spreading. Some of these properties (especially higher-angle modes and non-uniform current spreading) become even worse for VCSEL emitters that require a large aperture (e.g., with a diameter above 12 micrometers (μm)) for high-power LIDAR systems with a very narrow beam divergence.

Some implementations described herein relate to a multi-junction VCSEL structure with one or more low-contrast mirrors (e.g., low-contrast DBRs) that are disposed closer to a cavity that includes multiple active regions connected in series with one or more tunnel junctions in order to extend an effective length of the cavity and thereby manipulate overall beam divergence in the multi junction VCSEL. For example, some implementations described herein relate to one or more multi-junction VCSEL structures in which standard DBR mirror pairs that are nearest to the cavity, on one or both sides, may be replaced by DBR mirror pairs with relatively lower index contrast compared to the high index contrast DBR mirror pairs at the outer side (farther from the cavity). In this way, the multi junction VCSEL structures described herein can increase the effective length of the cavity and thereby reduce laser beam divergence by promoting lower order, lower angle modes. Furthermore, the lower contrast DBR mirror pairs may use lower aluminum (Al) composition layers, which may provide higher mobility and help the current spreading in the DBR, thereby reducing the resistance and voltage. In this way, the low-contrast mirrors may be used to manipulate beam divergence in a multi-junction VCSEL by filtering out higher-order modes and increasing a current injection profile into an emitter center. In this way, some implementations described herein may improve performance (e.g., light-current-voltage (L-I-V) characteristics and/or a far-field beam profile) in a multi junction VCSEL and/or optimize the power, efficiency, and/or divergence over temperature in a multi-junction VCSEL for short pulse (e.g., nanosecond) applications for iToF and dToF 3D sensing applications and/or automotive LIDAR applications, among other examples.

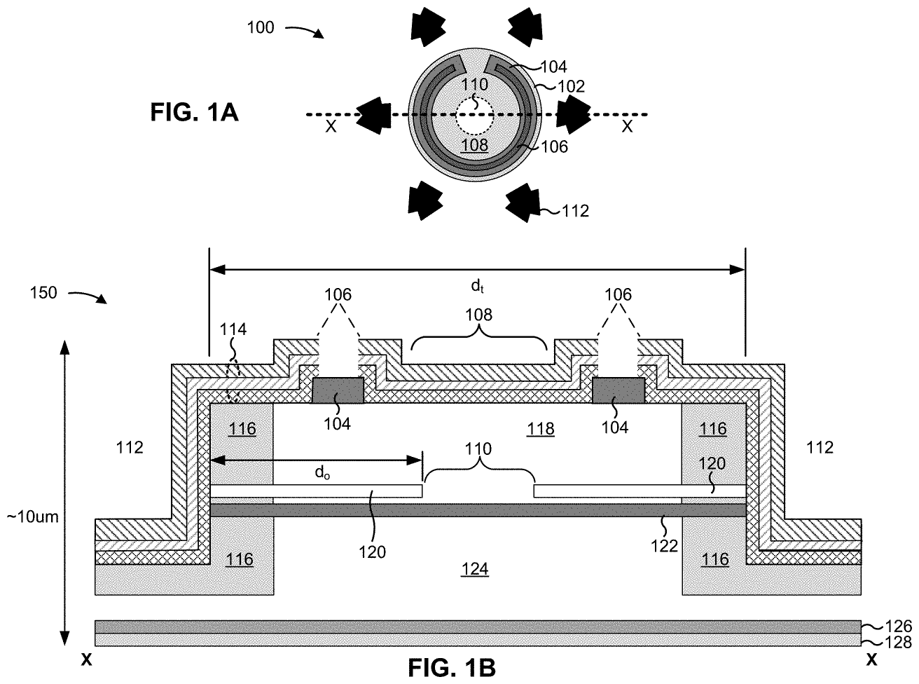

FIGS. 1A-1B are diagrams depicting a top view of an example emitter 100 and a cross-sectional view of the example emitter 100 along the line X-X, respectively. As shown in FIG. 1A, the example emitter 100 may include a set of emitter layers constructed in an emitter architecture. In some implementations, the example emitter 100 shown in FIGS. 1A-1B may correspond to one or more vertical-emitting devices described herein, such as a VCSEL.

As shown in FIG. 1A, the emitter 100 may include an implant protection layer 102 that is circular in shape in the illustrated example. In some implementations, implant protection layer 102 may have another shape, such as an elliptical shape, a polygonal shape, or the like. Implant protection layer 102 is defined based on a space between sections of implant material (not shown) included in the emitter 100.

As shown by the medium gray and dark gray areas in FIG. 1A, the emitter 100 includes an ohmic metal layer 104 (e.g., a p-ohmic metal layer or an n-ohmic metal layer) that is constructed in a partial ring shape (e.g., with an inner radius and an outer radius). The medium gray area shows an area of ohmic metal layer 104 covered by a protective layer (e.g., a dielectric layer or a passivation layer) of the emitter 100 and the dark gray area shows an area of ohmic metal layer 104 exposed by a via 106, described below. As shown, ohmic metal layer 104 overlaps with implant protection layer 102. Such a configuration may be used, for example, in the case of a p-up/top-emitting emitter 100. In the case of a bottom-emitting emitter 100, the configuration may be adjusted as needed.

The emitter 100 may include a protective layer (not shown in FIG. 1A) in which via 106 is formed (e.g., etched). The dark gray area shows an area of ohmic metal layer 104 that is exposed by via 106 (e.g., the shape of the dark gray area may be a result of the shape of via 106), and the medium gray area shows an area of ohmic metal layer 104 that is covered by a protective layer. The protective layer may cover all of the emitter other than the vias. As shown, via 106 is formed in a partial ring shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring shape or a split ring shape.

As further shown, the emitter 100 includes an optical aperture 108 in a portion of the emitter 100 within the inner radius of the partial ring shape of ohmic metal layer 104. The emitter 100 emits a laser beam via optical aperture 108. As further shown, the emitter 100 includes a current confinement aperture 110 (e.g., an oxide aperture formed by an oxidation layer of the emitter 100 (not shown)). Current confinement aperture 110 is formed below optical aperture 108.

As further shown in FIG. 1A, the emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, the emitter 100 may include additional layers, fewer layers, different layers, or differently arranged layers than those shown in FIG. 1A. For example, while the emitter 100 shown in FIG. 1A includes a set of six trenches 112, in practice, other configurations are possible, such as a compact emitter that includes five trenches 112, seven trenches 112, or another quantity of trenches. In some implementations, a trench 112 may encircle the emitter 100 to form a mesa structure dₜ. As another example, while the emitter 100 shown in FIG. 1A is a circular emitter design, in practice, other designs may be used, such as a rectangular emitter, a hexagonal emitter, an elliptical emitter, or the like. Additionally, or alternatively, a set of layers (e.g., one or more layers) of the emitter 100 may perform one or more functions described as being performed by another set of layers of the emitter 100, respectively.

Notably, while the design of the emitter 100 is described as including a VCSEL, other implementations are possible. For example, the design of the emitter 100 may apply in the context of another type of optical device, such as a light emitting diode (LED), or another type of vertical emitting (e.g., top emitting or bottom emitting) optical device. Additionally, the design of the emitter 100 may apply to emitters of any wavelength, power level, and/or emission profile. In other words, the emitter 100 is not particular to an emitter with a given performance characteristic.

As shown in FIG. 1B, the example cross-sectional view may represent a cross-section of the emitter 100 that passes through, or between, a pair of trenches 112 (e.g., as shown by the line labeled “X-X” in FIG. 1A). As shown, the emitter 100 may include a backside cathode layer 128, a substrate layer 126, a bottom mirror 124, an active region 122, an oxidation layer 120, a top mirror 118, an implant isolation material 116, a protective layer 114 (e.g., a dielectric passivation/mirror layer), and an ohmic metal layer 104. As shown, the emitter 100 may have, for example, a total height that is approximately 10 μm.

Backside cathode layer 128 may include a layer that makes electrical contact with substrate layer 126. For example, backside cathode layer 128 may include an annealed metallization layer, such as a gold germanium nickel (AuGeNi) layer, a palladium germanium gold (PdGeAu) layer, or the like.

Substrate layer 126 may include a base substrate layer upon which epitaxial layers are grown. For example, substrate layer 126 may include a semiconductor layer, such as a gallium arsenide (GaAs) layer, an indium phosphide (InP) layer, and/or another type of semiconductor layer.

Bottom mirror 124 may include a bottom reflector layer of the emitter 100. For example, bottom mirror 124 may include a DBR (e.g., an n-DBR).

Active region 122 may include a layer that confines electrons and defines an emission wavelength of the emitter 100. For example, active region 122 may be a quantum well (e.g., a single quantum well (SQW) or a multiple quantum well (MQW)). In some examples, the emitter 100 may include multiple stacked active regions 122 (e.g., two, three, four, five, six, or more active regions 122) that are connected in series with tunnel junctions (not shown) between the active regions 122. In some examples, the one or more active regions 122 (and any tunnel junctions in the case of multiple active regions 122) may form a cavity of the emitter 100.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an aluminum oxide (AlO_{X}) layer formed as a result of oxidation of an aluminum arsenide (AlAs) layer or an aluminum gallium arsenide (AlGaAs) layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround the emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of the emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, a lithographically defined intra-cavity mesa and regrowth, or the like.

Top mirror 118 may include a top reflector layer of the emitter 100. For example, top mirror 118 may include a DBR (e.g., a p-DBR).

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a silicon oxide (SiO_{X}) layer, a silicon nitride (SiN_{X}) layer, an aluminum oxide (AlO_{X}) layer, or other layers) that may be deposited by chemical vapor deposition, atomic layer deposition, and/or other suitable techniques on one or more other layers of the emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a titanium (Ti) and gold (Au) layer, a Ti and platinum (Pt) layer, an Au layer, or the like, through which electrical current may flow (e.g., through a bondpad (not shown) that contacts ohmic metal layer 104 through via 106). Ohmic metal layer 104 may be p-ohmic, n-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, the emitter 100 may be manufactured using a series of steps. For example, bottom mirror 124, active region(s) 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B are provided as an example. In practice, the emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of the emitter 100 and any layer may comprise more than one layer.

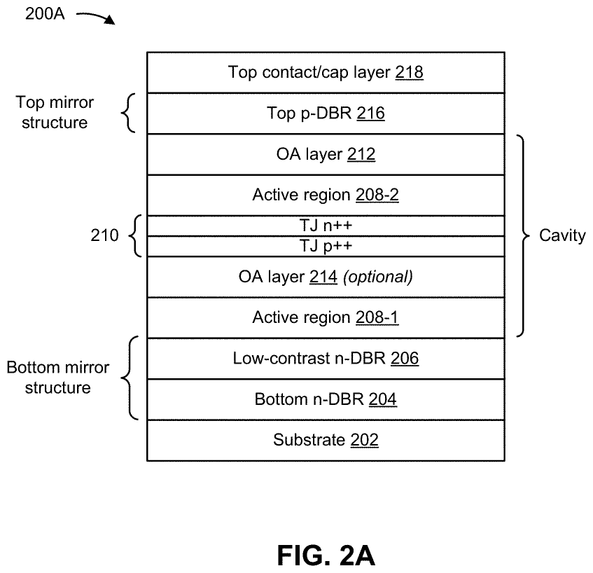

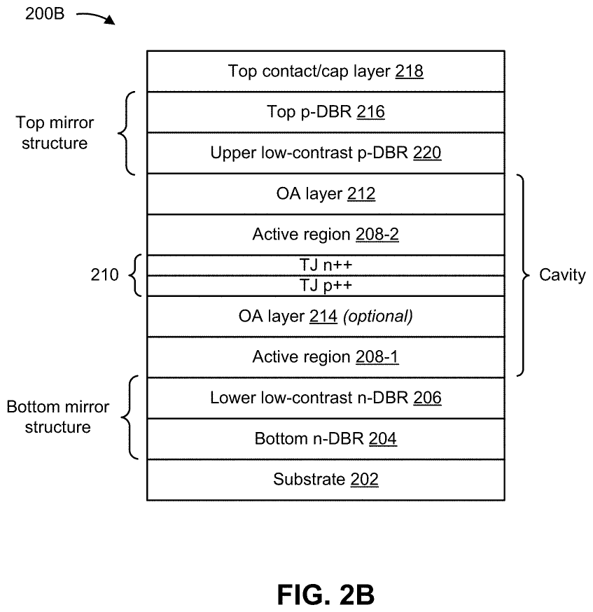

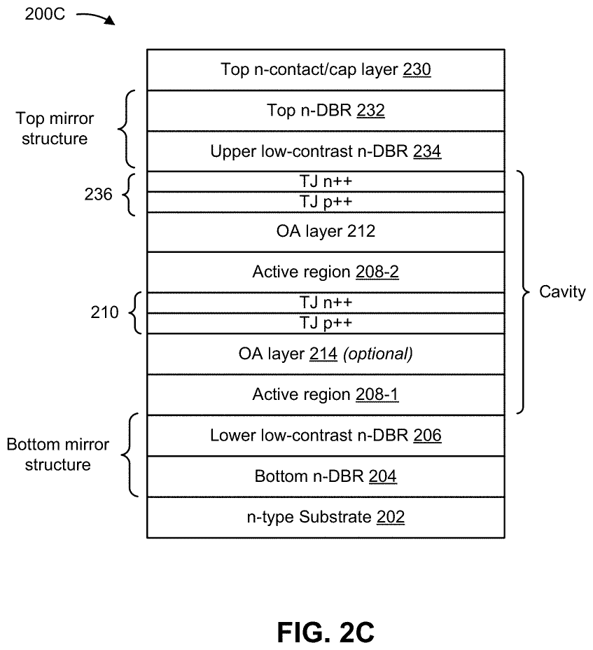

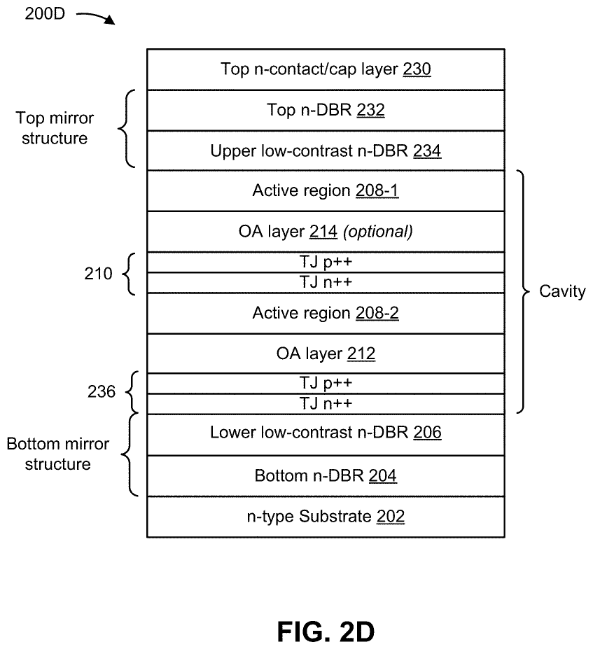

FIGS. 2A-2D are diagrams depicting cross-sectional views of example multi-junction emitter structures 200A-200D described herein. In some implementations, the multi-junction emitter structures 200A-200D may correspond to one or more vertical-emitting devices described herein, such as the emitter 100 shown in FIGS. 1A-1B and described in further detail above. For example, the multi junction emitter structures 200A-200D may be used in a single-emitter multi-junction VCSEL and/or a VCSEL array (e.g., where multiple emitters are arranged in a grid VCSEL array or a non-grid VCSEL array). As shown in FIGS. 2A-2B, the multi-junction emitter structures 200A, 200B include a set of emitter layers that are constructed in an emitter architecture (e.g., as described in connection with FIGS. 1A-1B, where multi junction emitter structures 200A-200D are different variants of the region that includes the optical aperture 108 and current confinement aperture shown in FIG. 1B). In some implementations, the multi-junction emitter structures 200A-200D may be used in a top-emitting multi junction VCSEL and/or a bottom-emitting multi-junction VCSEL.

As shown in FIGS. 2A-2D, the multi junction emitter structures 200A-200D may include a substrate 202 (e.g., an n-type semiconductor substrate) and a stack comprising set of layers (e.g., stacked epitaxial layers) that are formed (e.g., epitaxially grown) on the substrate 202. For example, as shown in FIG. 2A-2D, the set of stacked layers formed on the substrate 202 may include a bottom mirror structure, a top mirror structure, a top contact and/or cap layer 218 or 230 on the top mirror structure, and a cavity between the top mirror structure and the bottom mirror structure.

As shown in FIGS. 2A-2D, the substrate 202 includes a supporting material upon which or within which one or more layers or features of the multi-junction emitter structures 200A-200D are grown or fabricated. In some implementations, the substrate 202 comprises an n-type material. In some implementations, the substrate 202 comprises a semi-insulating type of material. In some implementations, the semi-insulating type of material may be used when the multi-junction emitter structures 200A-200D are used in one or more bottom-emitting emitters in order to reduce optical absorption from the substrate 202. In such an implementation, the multi-junction emitter structures 200A-200D may include a contact buffer (not shown) in or near the bottom mirror structure. In some implementations, the substrate 202 may be formed from a semiconductor material, such as GaAs, InP, or another type of semiconductor material. In some implementations, a bottom contact (e.g., a bottom n-contact) of the multi junction emitter structures 200A-200D can be made from a backside of the substrate 202. In some implementations, the bottom contact of the multi junction emitter structures 200A-200D can be made from a front side of the multi junction emitter structures 200A-200D. In some implementations, the front side contact can be achieved by, for example, etching a mesa step or trench to the substrate 202, or inserting a contact buffer in or near the bottom mirror structure.

In some implementations, the multi-junction emitter structures 200A-200D may be formed on a bottom metal (not shown), which includes a metal layer on a bottom surface of the substrate 202 (e.g., at a backside of the multi junction emitter structures 200A-200D). In some implementations, the bottom metal is formed from an n-type material. In some implementations, the bottom metal is a layer that makes electrical contact with the substrate 202. In some implementations, the bottom metal serves as an anode for the multi junction emitter structures 200A-200D. For example, in some implementations, the bottom metal may serve as a common anode for a group of sub-arrays of a VCSEL array, where the multi-junction emitter structures 200A-200D are one of the group of sub-arrays. In some implementations, the bottom metal may include an annealed metallization layer, such as a AuGeNi or PdGeAu layer.

In some implementations, the bottom mirror structure and the top mirror structure respectively form a bottom reflector and a top reflector of an optical resonator of the multi-junction emitter structures 200A-200D. For example, the bottom mirror structure and the top mirror structure may each include one or more DBRs, dielectric mirrors, or other mirror structure. In some implementations, the bottom mirror structure and the top mirror structure each include one or more layers (e.g., aluminum gallium arsenide (AlGaAs) layers) that are grown using a metal-organic chemical vapor deposition (MOCVD) technique, a molecular beam epitaxy (MBE) technique, or another technique.

In some implementations, as shown in FIGS. 2A-2D, the cavity disposed between the bottom mirror structure and the top mirror structure generally includes multiple active regions 208 (shown as MQW layers) where electrons and holes recombine to emit light and define the emission wavelength range of the multi-junction emitter structures 200A-200D. For example, as described herein, the multi-junction emitter structures 200A-200D are examples of a double-junction emitter where a tunnel junction 210 is used to connect two active regions 208-1, 208-2 that are embedded between one or more DBRs forming the top mirror structure and one or more DBRs forming the bottom mirror structure. Accordingly, as described herein, the example multi-junction emitter structures 200A-200D correspond to a double-junction VCSEL with a first active region 208-1 and a second active region 208-2 connected in series by a single tunnel junction 210 that includes heavily doped p-type and n-type semiconductor materials (respectively denoted p++ and n++) (e.g., with a doping level from 10¹⁹ to 10²⁰ cm⁻³). However, it will be appreciated that the cavity in the multi junction emitter structures 200A-200D may include two, three, four, five, six, or more active regions 208 with a tunnel junction 210 provided at each interface between a pair of active regions 208.

In addition, as shown, the cavity embedded between the top mirror structure and the bottom mirror structure may include one or more oxide aperture (OA) layers 212, 214. For example, the OA layer 212 provided above the active regions 208 may impose a lateral confinement on electric current and optical mode, and an additional OA layer 214 may optionally be added in the bottom junction to enhance such confinement. For example, in FIGS. 2A-2B, the OA layer 212 that imposes the lateral confinement on the electric current and optical mode may be disposed between the upper active region 208-2 and the top mirror structure. Alternatively, in FIGS. 2C-2D, the OA layer 212 that imposes the lateral confinement on the electric current and optical mode may be disposed between the upper active region 208-2 and an additional tunnel junction 236, which is described in more detail below. In some implementations, in cases where the cavity includes the (optional) additional OA layer 214, the additional OA layer 214 may be located at a p-side and/or an n-side of one or more of the active regions 208. For example, as shown in FIGS. 2A-2D, the additional OA layer 214 may be disposed between the first active region 208-1 and the tunnel junction region 210 connecting the first active region 208-1 and the second active region 208-2. Alternatively, in other examples, the additional OA layer 214 may be disposed between the tunnel junction 210 and the second active region 208-2, between the first active region 208-1 and the bottom mirror structure, or the like. Alternatively, in some implementations the multi-junction emitter structures 200A-200D may be free of an OA layer (e.g., the multi junction emitter structures 200A-200D may not utilize oxide confinement). For example, rather than using one or more OA layers 212, 214, some implementations may enable current and mode confinement using a structure that includes one or more implant passivation layers, one or more mesa or moat trench isolation layers, and/or one or more buried tunnel junction layers, among other examples.

In some implementations, as shown in FIGS. 2A-2D, the example multi-junction emitter structures 200A-200D may generally include one or more DBR pairs in which a low-contrast DBR disposed on an inner side of the stack nearer to the cavity is paired with a high-contrast DBR disposed on an outer side of the stack, farther from the cavity. For example, as described herein, a high-contrast DBR means that a refractive index profile difference between high-index and low-index DBR layers is relatively large, and a low-contrast DBR means that the refractive index profile difference between high-index and low-index DBR layers is relatively small. Accordingly, the one or more DBR pairs may be used to form the bottom mirror structure and/or the top mirror structure in order to filter out higher-order modes and increase a current injection profile into a center of the multi junction emitter structures 200A-200D and thereby manipulate a beam divergence in the multi junction emitter structures 200A-200D. For example, by providing a low-contrast DBR on an inner side nearest to the cavity that includes the multiple active regions 208, the example multi junction emitter structures 200A-200D can increase an effective length of the cavity so as to reduce the laser beam divergence by promoting lower order, lower angle modes. Furthermore, the low-contrast DBR on the inner side may use lower aluminum (Al) compositions that could provide higher mobility and help spread current, thereby reducing resistance and voltage.

In one example, as shown in FIG. 2A, the bottom mirror structure of multi-junction emitter structure 200A includes a bottom (e.g., high-contrast) n-DBR 204 formed on the substrate 202 on an outer side of the stack farther from the cavity and a low-contrast n-DBR 206 formed on the bottom n-DBR 204 on an inner side of the stack nearer to the cavity. In the multi-junction emitter structure 200A shown in FIG. 2A, only the bottom mirror structure includes a low-contrast n-DBR 206, and the top mirror structure is formed from a top (e.g., high-contrast) p-DBR 216. Alternatively, in the example multi junction emitter structure 200B shown in FIG. 2B, the top mirror structure includes a top (e.g., high-contrast) p-DBR 216 on an outer side of the stack and a low-contrast p-DBR 220 on an inner side of the stack nearer to the cavity. In general, the top mirror structure may be formed from one or more p-DBRs in cases where a top contact or cap layer 218 is formed from a p-type semiconductor material.

Alternatively, as shown in FIGS. 2C-2D, a top contact or cap layer 230 may be formed from an n-type semiconductor material, in which case the top mirror structure may be formed from one or more n-DBRs (e.g., a top n-DBR 232 on an outer side of the stack farther from the cavity and an upper low-contrast n-DBR 234 on an inner side of the stack nearer to the cavity). In these examples, the cavity includes an additional tunnel junction 236 to convert a polarity such that all or part of the p-DBR(s) shown in FIGS. 2A-2B can be replaced by n-DBRs 232, 234. In this way, when the top contact or cap layer 230 is formed from an n-type semiconductor material, the negative-positive-intrinsic-negative (NPIN) carrier type configuration shown in FIG. 2C or the negative-intrinsic-positive-negative (NIPN) carrier type configuration shown in FIG. 2D may be used, where the cavity in the NPIN configuration is vertically inverted relative to the cavity in the NIPN configuration (and vice versa). For example, as described herein, areas or layers associated with a negative carrier type may be primarily used for electron conduction, and areas or layers associated with a positive carrier type may be primarily used for hole (e.g., positive charge) conduction. Accordingly, in some implementations, the NPIN and NIPN configurations shown in FIGS. 2C-2D may help to reduce optical absorption due to electrons having lower free-carrier absorption than holes. Additionally, or alternatively, the multi junction emitter structures 200C-200D shown in FIGS. 2C-2D may provide an additional opportunity for narrower divergence because an n-type carrier typically has a higher mobility and can enhance carrier spreading more uniformly across the OA layer(s) 212, 214 compared to a top mirror structure formed only from one or more p-DBRs. In this way, compared to the multi-junction emitter structures 200A-200B, the multi-junction emitter structures 200C-200D shown in FIGS. 2C-2D may generate a higher gain in the center (e.g., active) region, which may have a more significant impact on large OA designs. Furthermore, NPIN or NIPN VCSEL structures grown on n-type substrates (e.g., as shown in FIGS. 2C-2D) may increase the effectiveness of the upper low-contrast p-DBR 220 due to n-type DBRs having a relatively lower optical absorption than p-type DBRs.

Accordingly, as described herein, some implementations relate to multi-junction emitter structures in which a bottom mirror structure and/or a top mirror structure include a low-contrast DBR disposed on an inner side of the stack nearer to the cavity that is paired with a high-contrast DBR disposed on an outer side of the stack farther from the cavity. In this way, the one or more low-contrast DBRs may be used to filter out higher-order modes and increase a current injection profile into a center of a multi junction emitter structure. For example, providing a low-contrast DBR on the inner side nearest to the cavity can increase an effective length of the cavity. For example, in a typical GaAs-based VCSEL, the top and bottom DBRs that sandwich the cavity include higher Al composition AlGaAs and lower Al composition AlGaAs or GaAs, and may also include grading layers between the DBRs to reduce resistance. Accordingly, because a refractive index value generally decreases with increasing Al composition in an AlGaAs semiconductor alloy, a low-contrast DBR (e.g., the low-contrast n-DBR 206 used in the bottom mirror structure and/or the low-contrast p-DBR 220 or n-DBR 234 used in the top mirror structure) may use lower Al compositions to increase the effective length of the cavity. For example, in a conventional Fabry-Pérot cavity, the length of the cavity is straightforward and determined by the distance between the mirrors. However, for a VCSEL with a top mirror structure and a bottom mirror structure (e.g., as shown in FIGS. 2A-2D), the cavity length includes the length of the actual cavity between the top mirror structure and the bottom mirror structure and the length of the effective cavity penetrating into the top mirror structure and the bottom mirror structure.

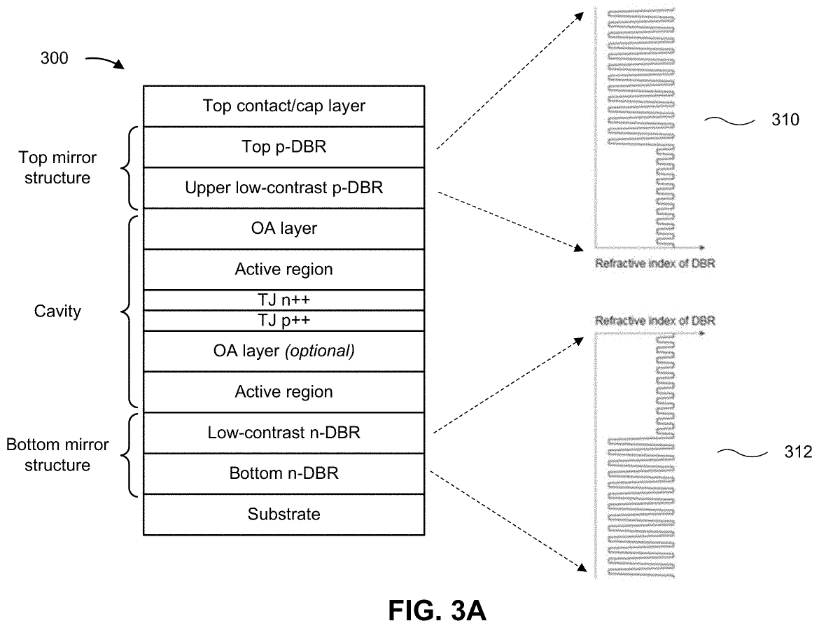

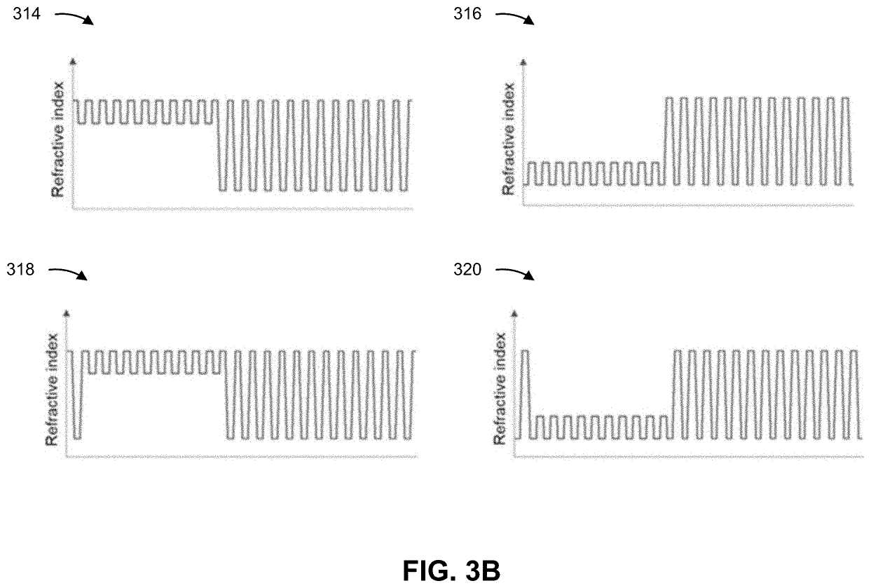

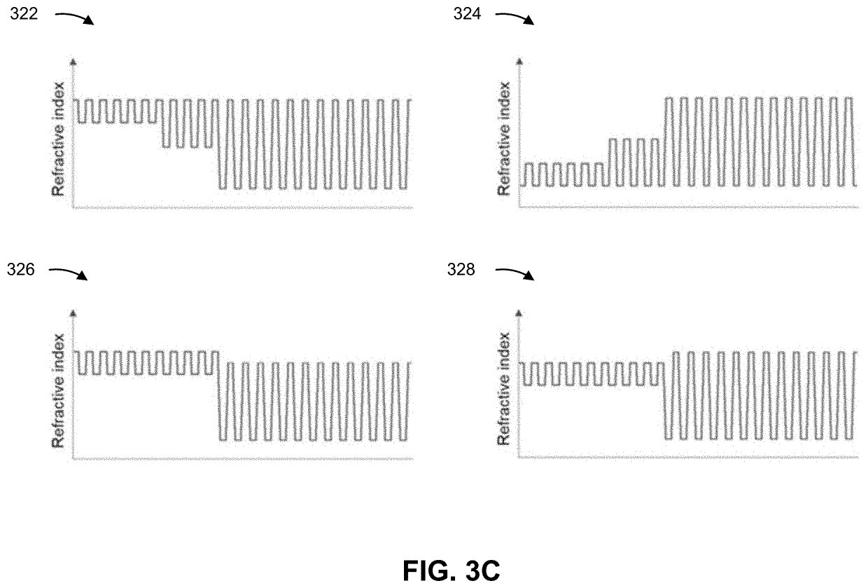

For example, as shown in FIGS. 3A-3C, the effective length of the cavity may generally depend on the refractive index difference between high-index and low-index DBR layers (e.g., a refractive index profile difference, such as an index magnitude, a contrast and number of DBR pairs, between a high-contrast DBR at an outer side of the stack farther from the cavity and a low-contrast DBR on an inner side of the stack nearer to the cavity). For example, in some implementations, a smaller difference in refractive index profile (e.g., a lower contrast) generally results in a longer effective cavity relative to a larger difference in refractive index profile (e.g., a higher contrast). In this way, beam divergence in a multi-junction emitter (e.g., a single multi-junction VCSEL or a VCSEL array) may be manipulated by controlling the number of high-contrast/low-contrast DBR pairs and/or by controlling the contrast of the low-contrast DBR(s). For example, in some implementations, a larger number of low-contrast DBR pairs and/or a lower contrast for the low-contrast DBR(s) may increase the effective cavity length and thereby generate a narrower beam divergence. Alternatively, using fewer low-contrast DBR pairs and/or a higher contrast for the low-contrast DBR(s) may decrease the effective cavity length and thereby generate a wider beam divergence.

The number, arrangement, thicknesses, order, symmetry, and/or the like, of layers shown in FIGS. 2A-2D are provided as an example. In practice, a multi junction VCSEL may include additional layers, fewer layers, different layers, differently constructed layers, or differently arranged layers than those shown in FIGS. 2A-2D. For example, a multi-junction VCSEL may include a spacer layer and/or an additional DBR layer close to the tunnel junction 210 and the OA layer 212 and/or the OA layer 214. Additionally, or alternatively, a set of layers (e.g., one or more layers) shown in FIGS. 2A-2D may perform one or more functions described as being performed by another set of layers and any layer may comprise more than one layer.

FIGS. 3A-3C are diagrams depicting examples of refractive index profile differences between high-contrast outer mirrors and low-contrast inner mirrors in an example multi-junction emitter described herein. For example, FIG. 3A illustrates an example multi junction emitter structure 300 in which a cavity includes multiple active regions that are connected in series by one or more tunnel junctions between each pair of active regions. As shown in FIG. 3A, the cavity is embedded between a bottom mirror structure and a top mirror structure, one or more of which include a low-contrast DBR (e.g., on an inner side of the stack, closer to the cavity) that is paired with a high-contrast DBR (e.g., on an outer side of the stack farther from the cavity). For example, in FIG. 3A, the bottom mirror structure includes a bottom n-DBR on an outer side of the stack farther from the cavity and a lower low-contrast n-DBR on an inner side of the stack nearer to the cavity, and the top mirror structure includes a top p-DBR on an outer side of the stack farther from the cavity and an upper low-contrast p-DBR on an inner side of the stack nearer to the cavity. However, it will be appreciated that different configurations can be used for the number and/or composition (e.g., n-type or p-type) of the low-contrast DBRs, as described above with reference with to FIGS. 2A-2D.

In some implementations, to minimize carrier absorption loss, the low-contrast DBR located in the inner side of the stack that is closer to the cavity has a relatively lower doping than the high-contrast DBR located on the outer side of the stack that is farther from the cavity. In some implementations, the manipulation of beam divergence may depend on the quantity of DBR pairs and/or a contrast of the low-contrast DBRs. For example, as described above, using a larger number of low-contrast DBR pairs and/or a lower contrast for the low-contrast DBR(s) may increase the effective cavity length and thereby generate a narrower beam divergence, and using fewer low-contrast DBR pairs and/or a higher contrast for the low-contrast DBR(s) may decrease the effective cavity length and thereby generate a wider beam divergence. Furthermore, as described herein, an effective length of the cavity (which may impact the beam divergence) may depend on a refractive index profile difference between the high-contrast DBR and low-contrast DBR layers that are used to form the top and/or bottom mirror structures. For example, in FIG. 3A, reference number 310 depicts a refractive index profile difference between the upper low-contrast p-DBR and the top p-DBR forming the top mirror structure, and reference number 312 depicts a refractive index profile difference between the lower low-contrast n-DBR and the bottom n-DBR forming the bottom mirror structure. For example, in some implementations, the low-contrast DBR(s) on the inner side of the stack nearer to the cavity may have a lower Al composition than the high-contrast DBR(s) on the outer side of the stack farther from the cavity, which may result in the low-contrast DBR(s) having a higher refractive index than the high-contrast DBR(s) (e.g., based on the refractive index value decreasing with increasing Al composition).

As shown in FIGS. 3B-3C, the combination of low-contrast inner DBRs and high-contrast outer DBRs may have different configurations to enable beam divergence to be manipulated in different ways. For example, in FIG. 3B, reference number 314 depicts a refractive index profile difference between a high-contrast DBR paired with a high-index low-contrast DBR, reference number 316 depicts a refractive index profile difference between a high-contrast DBR paired with a low-index low-contrast DBR, and reference numbers 318 and 320 depict refractive index profile differences between a high-contrast DBR paired with an additional one pair, two pairs, or a few pairs of high-contrast DBRs inserted in the inner side of the stack, closer to the cavity. In other examples, as shown in FIG. 3C, reference number 322 depicts a refractive index profile difference between a high-contrast DBR paired with a two-step high-index low-contrast DBR (e.g., where the refractive index changes in two steps), reference number 324 depicts a refractive index profile difference between a high-contrast DBR paired with a two-step low-index low-contrast DBR, reference number 326 depicts a refractive index profile difference between a high-contrast DBR paired with a higher high-index low-contrast DBR, and reference number 328 depicts a refractive index profile difference between a high-contrast DBR paired with a lower high-index low-contrast DBR. Other examples may include only the upper or only the lower DBR including low-contrast DBRs, the upper and lower DBRs having different contrasts for low-contrast DBRs and/or high contrast DBRs, and/or more than two steps or gradually-changed low-contrast DBRs.

The number, arrangement, thicknesses, order, symmetry, refractive indexes, or the like, of layers shown in FIGS. 3A-3C are provided as examples. In practice, a multi-junction emitter may include additional layers, fewer layers, different layers, differently constructed layers, differently arranged layers, or different refractive indexes than those shown in FIGS. 3A-3C. Additionally, or alternatively, a set of layers (e.g., one or more layers) shown in FIGS. 3A-3C may perform one or more functions described as being performed by another set of layers shown in FIGS. 3A-3C and any layer may comprise more than one layer.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” or the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A multi junction vertical cavity surface emitting laser (VCSEL), comprising:
a substrate;
a top contact; and
a set of layers, formed between the substrate and the top contact, comprising:
a high-contrast p-type distributed Bragg reflector (p-DBR);
a high-contrast n-type distributed Bragg reflector (n-DBR);
a cavity comprising a first active region, a second active region, and a tunnel junction connecting the first active region and the second active region,
wherein the cavity is disposed between the high-contrast p-DBR and the high-contrast n-DBR; and
a low-contrast n-DBR disposed between the high-contrast n-DBR and the cavity.

2. The multi-junction VCSEL of claim 1, wherein the set of layers further comprises:
an oxide aperture layer disposed between the high-contrast p-DBR and the cavity.

3. The multi-junction VCSEL of claim 2, wherein:
the oxide aperture layer is a first oxide aperture layer, and
the set of layers further comprises a second oxide aperture layer disposed within the cavity between the tunnel junction and the first active region or the second active region.

4. The multi-junction VCSEL of claim 2, wherein the set of layers further comprises:
a low-contrast p-DBR disposed between the high-contrast p-DBR and the cavity.

5. The multi-junction VCSEL of claim 1, wherein the tunnel junction is a positive-negative junction comprising a doped p-type semiconductor layer and a doped n-type semiconductor layer adjacent to the doped p-type semiconductor layer.

6. The multi-junction VCSEL of claim 1, wherein an effective length of the cavity is based on a refractive index profile difference between the low-contrast n-DBR and the high-contrast n-DBR.

7. The multi-junction VCSEL of claim 1, wherein the low-contrast n-DBR has a lower doping level than a doping level of the high-contrast n-DBR.

8. A device, comprising:
a substrate;
a top contact; and
a stack comprising a set of layers, formed between the substrate and the top contact, the set of layers comprising:
a cavity comprising a first active region, a second active region, and a tunnel junction connecting the first active region and the second active region;
a first distributed Bragg reflector (DBR) pair comprising a high-contrast p-type DBR (p-DBR) and a low-contrast p-DBR between the cavity and the top contact; and
a second DBR pair comprising a high-contrast n-type DBR (n-DBR) and a low-contrast n-DBR between the cavity and the substrate,
wherein the low-contrast p-DBR and the low-contrast n-DBR are located on an inner side of the stack, and
wherein the high-contrast p-DBR and the high-contrast n-DBR are located on an outer side of the stack.

9. The device of claim 8, wherein the set of layers further comprises:
one or more layers arranged to impose a lateral confinement on electric current and optical modes within the cavity.

10. The device of claim 9, wherein the one or more layers arranged to impose the lateral confinement on the electric current and optical modes include one or more oxide aperture layers, implant passivation layers, mesa or moat trench isolation layers, or buried tunnel junction layers.

11. The device of claim 8, wherein the cavity has an effective length based on a refractive index profile difference between the low-contrast n-DBR and the high-contrast n-DBR and a refractive index profile difference between the low-contrast p-DBR and the high-contrast p-DBR.

12. The device of claim 8, wherein the substrate is an n-type substrate or a semi-insulating substrate with a contact buffer inserted in or near the second DBR pair.

13. The device of claim 8, wherein the device is a top-emitting multi junction vertical cavity surface emitting laser.

14. The device of claim 8, wherein the device is a bottom-emitting multi-junction vertical cavity surface emitting laser.

15. A multi junction vertical cavity surface emitting laser (VCSEL), comprising:
an n-type substrate;
an n-type top contact; and
a stack comprising a set of layers, formed between the n-type substrate and the n-type top contact, the set of layers comprising:
a cavity comprising a first active region, a second active region, and a first tunnel junction connecting the first active region and the second active region;
an upper n-type distributed Bragg reflector (n-DBR) pair comprising an upper high-contrast n-DBR and an upper low-contrast n-DBR disposed between the cavity and the n-type top contact;
a lower n-DBR pair comprising a lower high-contrast n-DBR and a lower low-contrast n-DBR disposed between the cavity and the n-type substrate; and
a second tunnel junction disposed between the cavity and the upper n-DBR pair or the lower n-DBR pair,
wherein the upper low-contrast n-DBR and the lower low-contrast n-DBR are located on an inner side of the stack, and
wherein the upper high-contrast n-DBR and the lower high-contrast n-DBR are located on an outer side of the stack.

16. The multi-junction VCSEL of claim 15, wherein the second tunnel junction inverts a polarity between the cavity and the upper n-DBR pair or the lower n-DBR pair.

17. The multi-junction VCSEL of claim 15, wherein the set of layers further comprises:
one or more layers arranged to impose a lateral confinement on electric current and optical modes within the cavity.

18. The multi-junction VCSEL of claim 15, wherein the cavity has an effective length based on a refractive index profile difference between the upper low-contrast n-DBR and the upper high-contrast n-DBR and a refractive index profile difference between the lower low-contrast n-DBR and the lower high-contrast n-DBR.

19. The multi-junction VCSEL of claim 15, wherein the set of layers have a negative-positive-intrinsic-negative (NPIN) carrier type configuration.

20. The multi-junction VCSEL of claim 15, wherein the set of layers have a negative-intrinsic-positive-negative (NIPN) carrier type configuration.
